(19) United States
(12) Patent Application Publication
(10) Pub. No.: US 2022/0067426 A1
(43) Pub. Date: Mar. 3, 2022

(54) SEPARATION DISTANCE BETWEEN FEATURE VECTORS FOR SEMI-SUPERVISED HOTSPOT DETECTION AND CLASSIFICATION

(71) Applicant: Siemens Industry Software Inc., Plano, TX (US)

(72) Inventors: Mohamed Bahnas, Cupertino, CA (US); Ilhami Torunoglu, San Jose, CA (US)

(21) Appl. No.: 17/006,002

(22) Filed: Aug. 28, 2020

(51) Int. Cl. G06K 9/62

(52) U.S. Cl. CPC G06K 9/6215; G06K 9/627; G06K 9/6228; G06K 9/6256

(57) ABSTRACT

Systems and methods for semi-supervised hotspot detection and classification are disclosed. Hotspots comprise layout pattern that induce printability issues in the lithography process. To detect hotspots, one feature vector, such as an n-dimensional feature vector, is compared with other feature vector(s). The comparison between feature vectors may comprise determining a distance, such as a Euclidian distance, in order to determine closeness between the feature vectors. For example, a training dataset, that includes known hotspots and known non-hotspots, is used in order to determine threshold(s). In particular, for one, some, or all of the known hotspots in the training dataset, a distance to a closest known hotspot and a closest known non-hotspot may be calculated to determine the threshold(s). In turn, a layout under examination, which includes indeterminate spots, may be analyzed using the known hotspots in the training dataset and the threshold(s) to identify the indeterminate spots as potential hotspots.

### FIELD

The present disclosure relates to the field of semiconductor layout analysis, and specifically relates to detecting hotspots in a semiconductor layout.

### BACKGROUND

Electronic circuits, such as integrated microcircuits, are used in a variety of products, from automobiles to microwaves to personal computers. Designing and fabricating integrated circuit devices typically involves many steps, sometimes referred to as a “design flow.” The particular steps of the design flow often are dependent upon the type of integrated circuit, its complexity, the design team, and the integrated circuit fabricator or foundry that will manufacture the microcircuit. Typically, software and hardware “tools” verify the design at various stages of the design flow by running software simulators and/or hardware emulators. These steps aid in the discovery of errors in the design, and allow the designers and engineers to correct or otherwise improve the design.

For example, a layout design (interchangeably referred to as a layout) may be derived from an electronic circuit design. The layout design may comprise an integrated circuit (IC) layout, an IC mask layout, or a mask design. In particular, the layout design may be a representation of an integrated circuit in terms of planar geometric shapes which correspond to the patterns of metal, oxide, or semiconductor layers that make up the components of the integrated circuit. The layout design can be one for a whole chip or a portion of a full-chip layout design.

Typically, modeling and simulation applications analyze the layout design around a point of interest (POI), whose manufacturing behavior is being modeled or simulated as well as first principles information about the process physics of the associated layer. As one example, the POI may comprise a point in the layout design that has coordinates (x, y).

The layout design may be analyzed for one or more aspects. As one example, the layout design may be analyzed to identify or detect hotspots. For example, as feature sizes in chip design and semiconductor manufacturing technology node scale down further, there are challenges to cope with the sub-wavelength lithography gap. Even with various sophisticated techniques such as resolution enhancement techniques (RETs), multi-pattern lithography (MPL), and design for manufacturing (DFM), semiconductor manufacturing process may often face lithography hotspots. Thus, a hotspot may comprise a layout pattern that may induce printability issues in lithography processes. As merely one example, a pinching-type hotspot may result in an open or pinching defect and a bridging-type hotspot can lead to a bridge defect. In this regard, analysis of the layout design may detect hotspots, such as disclosed in US Patent Application Publication No. 2019/0087526 A1, incorporated by reference herein in its entirety.

### BRIEF DESCRIPTION OF THE DRAWINGS

The accompanying drawings, which are incorporated in and constitute a part of this specification, illustrate various aspects of the invention and together with the description, serve to explain its principles. Wherever convenient, the same reference numbers will be used throughout the drawings to refer to the same or like elements.

FIG. 1 illustrates an example of a computing system that may be used to implement various embodiments of the disclosed technology.

FIG. 2 illustrates an example of a multi-core processor unit that may be used to implement various embodiments of the disclosed technology.

FIG. 3A is a first block diagram for a semi-supervised methodology for inspecting potential hotspots.

FIG. 3B is a second block diagram for a semi-supervised methodology for inspecting potential hotspots.

FIG. 4A is an illustration of calculating Euclidian distance for a feature vector between a known hotspot and other known hotspots and other known non-hotspots.

FIG. 4B is a first scatter plot of the hotspot/hotspot and hotspot/non-hotspot distances calculated in FIG. 4A.

FIG. 5A is a second scatter plot of the hotspot/hotspot and hotspot/non-hotspot distances and a determined threshold.

FIG. 5B is a graph of the distance threshold versus false alarm rate.

FIG. 6A is a graph of the separation distance versus frequency.

FIG. 6B is a graph of the separation distance versus false alarm rate for the data in FIG. 6A.

FIG. 7A is an illustration depicting clustering and then using separation distance (indicated by a ring) to identify potential hotspots.

FIG. 7B is a graph of the size of the ring versus false alarm rate for the methodology of FIG. 7A.

FIG. 8A is an illustration using separation distance to identify potential hotspots.

FIG. 8B is a graph of the size of the ring versus false alarm rate for the methodology of FIG. 8A.

FIG. 9A is a third scatter plot of hotspot/hotspot distance versus hotspot/non-hotspot distance.

FIG. 9B is a graph of the threshold versus false alarm rate for the data in FIG. 9A.

FIG. 10 is a block diagram of the threshold determination engine and the threshold application engine.

FIG. 11 is a first flow chart for determining and using separation distance threshold(s).

FIG. 12A is a second flow chart for determining and using separation distance threshold(s).

FIG. 12B illustrates a first expanded flow diagram for block 1206 of FIG. 12A.

FIG. 12C illustrates a second expanded flow diagram for block 1206 of FIG. 12A.

FIG. 13 is a flow chart for determining one or both of the optimum separation distance threshold or the optimum feature vector.

FIG. 14 is a flow chart for analyzing indeterminate spots in a new layout to identify hotspots.

### DETAILED DESCRIPTION OF EMBODIMENTS

### General Considerations

Various aspects of the present disclosed technology relate to hotspot detection based on a separation distance between two or more feature vectors. In the following description, numerous details are set forth for the purpose of explanation. However, one of ordinary skill in the art will realize that the disclosed technology may be practiced without the use of these specific details. In other instances, well-known features have not been described in detail to avoid obscuring the present disclosed technology.

Some of the techniques described herein can be implemented in software instructions stored on one or more non-transitory computer-readable media, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Moreover, for the sake of simplicity, the disclosed flow charts and block diagrams typically do not show the various ways in which particular methods can be used in conjunction with other methods. Additionally, the detailed description sometimes uses terms like “perform”, “generate,” “access,” and “determine” to describe the disclosed methods. Such terms are high-level abstractions of the actual operations that are performed. The actual operations that correspond to these terms will vary depending on the particular implementation and are readily discernible by one of ordinary skill in the art.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one micro device, such as data to be used to form multiple micro devices on a single wafer.

### Illustrative Operating Environment

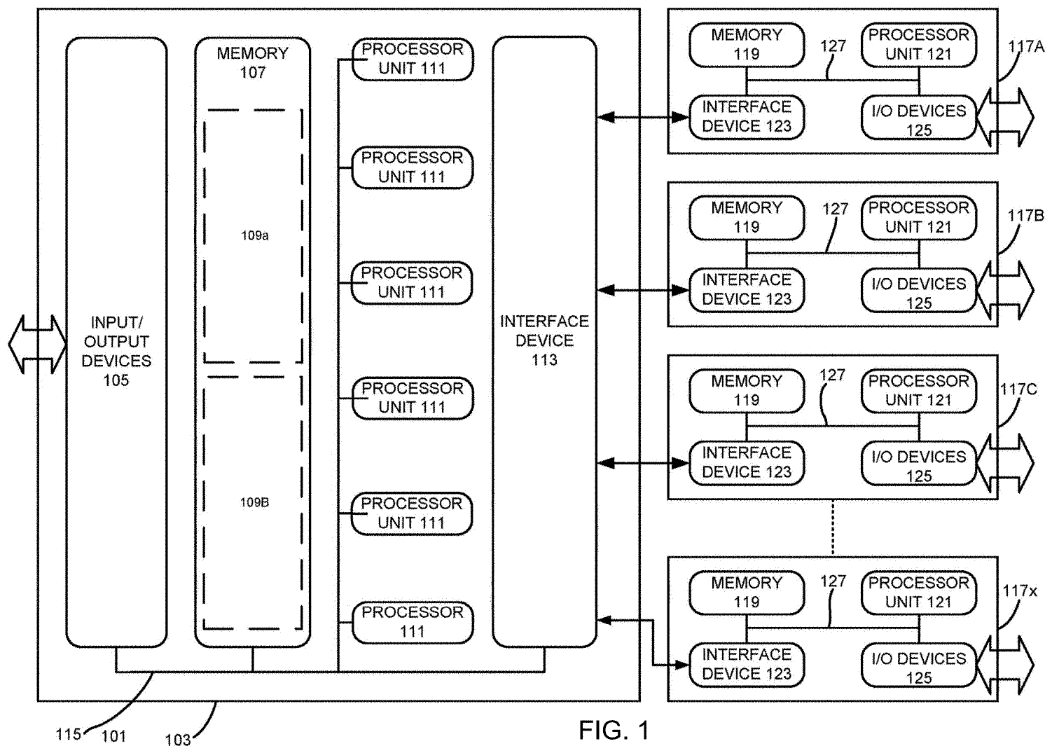

The execution of various electronic design processes according to embodiments of the disclosed technology may be implemented using computer-executable software instructions executed by one or more programmable computing devices. Because these embodiments of the disclosed technology may be implemented using software instructions, the components and operation of a generic programmable computer system on which various embodiments of the disclosed technology may be employed will first be described. Further, because of the complexity of some electronic design processes and the large size of many circuit designs, various electronic design automation tools are configured to operate on a computing system capable of simultaneously running multiple processing threads. The components and operation of a computer network having a host or master computer and one or more remote or servant computers therefore will be described with reference to FIG. 1. This operating environment is only one example of a suitable operating environment, however, and is not intended to suggest any limitation as to the scope of use or functionality of the disclosed technology.

In FIG. 1, the computer network 101 includes a master computer 103. In the illustrated example, the master computer 103 is a multi-processor computer that includes a plurality of input/output devices 105 and a memory 107. The input/output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include non-magnetic and magnetic cassettes, magnetic tapes, magnetic disks or other magnetic storage devices, punched media, holographic storage devices, or any other medium that can be used to store desired information.

As will be discussed in detail below, the master computer 103 runs a software application for performing one or more operations according to various examples of the disclosed technology. Accordingly, the memory 107 stores software instructions 109A that, when executed, will implement a software application for performing one or more operations, such as the operations disclosed herein. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device, a graphics processor unit (GPU) device, or the like. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations, include using an application-specific integrated circuit (ASIC) or a field programmable gate array (FPGA). The interface device 113, the processor units 111, the memory 107 and the input/output devices 105 are connected together by a bus 115.

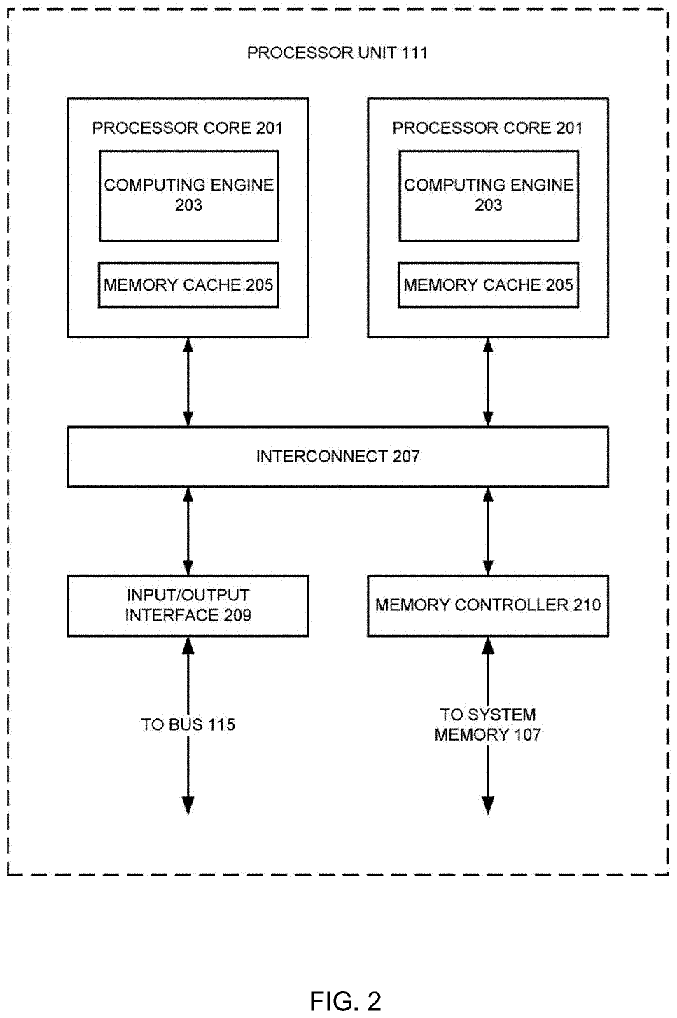

With some implementations of the disclosed technology, the master computer 103 may employ one or more processing units 111 having more than one processor core. Accordingly, FIG. 2 illustrates an example of a multi-core processor unit 111 that may be employed with various embodiments of the disclosed technology. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 111. With some processor cores 201, such as the Cell microprocessor created by Sony Corporation, Toshiba Corporation and IBM Corporation, the interconnect 207 may be implemented as an interconnect bus. With other processor units 111, however, such as the Opteron™ and Athlon™ dual-core processors available from Advanced Micro Devices of Sunnyvale, Calif., the interconnect 207 may be implemented as a system request interface device. In any case, the processor cores 201 communicate through the interconnect 207 with an input/output interface 209 and a memory controller 210. The input/output interface 209 provides a communication interface between the processor unit 111 and the bus 115. Similarly, the memory controller 210 controls the exchange of information between the processor unit 111 and the system memory 107. With some implementations of the disclosed technology, the processor units 111 may include additional components, such as a high-level cache memory accessible shared by the processor cores 201.

While FIG. 2 shows one illustration of a processor unit 111 that may be employed by some embodiments of the disclosed technology, it should be appreciated that this illustration is representative only, and is not intended to be limiting. Also, with some implementations, a multi-core processor unit 111 can be used in lieu of multiple, separate processor units 111. For example, rather than employing six separate processor units 111, an alternate implementation of the disclosed technology may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the servant computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the servant computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each servant computer 117 may include a memory 119, a processor unit 121, an interface device 123, and, optionally, one more input/output devices 125 connected together by a system bus 127. As with the master computer 103, the optional input/output devices 125 for the servant computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations (e.g., using an ASIC or an FPGA). Still further, one or more of the processor units 121 may have more than one core, as described with reference to FIG. 2 above. For example, with some implementations of the disclosed technology, one or more of the processor units 121 may be a Cell processor. The memory 119 then may be implemented using any combination of the computer readable media discussed above. Like the interface device 113, the interface devices 123 allow the servant computers 117 to communicate with the master computer 103 over the communication interface.

In the illustrated example, the master computer 103 is a multi-processor unit computer with multiple processor units 111, while each servant computer 117 has a single processor unit 121. It should be noted, however, that alternate implementations of the disclosed technology may employ a master computer having single processor unit 111. Further, one or more of the servant computers 117 may have multiple processor units 121, depending upon their intended use, as previously discussed. Also, while only a single interface device 113 or 123 is illustrated for both the master computer 103 and the servant computers, it should be noted that, with alternate embodiments of the disclosed technology, either the computer 103, one or more of the servant computers 117, or some combination of both may use two or more different interface devices 113 or 123 for communicating over multiple communication interfaces.

With various examples of the disclosed technology, the master computer 103 may be connected to one or more external data storage devices. These external data storage devices may be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the disclosed technology, one or more of the servant computers 117 may alternately or additionally be connected to one or more external data storage devices. Typically, these external data storage devices will include data storage devices that also are connected to the master computer 103, but they also may be different from any data storage devices accessible by the master computer 103.

It also should be appreciated that the description of the computer network illustrated in FIG. 1 and FIG. 2 is provided as an example only, and it not intended to suggest any limitation as to the scope of use or functionality of alternate embodiments of the disclosed technology.

Detection of Hotspots and/or Non-Hotspots

As discussed in the background, in a semiconductor fabrication process, the yield may be negatively impacted by defects that appear systematically within specific patterns of the physical layout design. Those defective patterns may be termed hotspots and may exist due to various root causes. Existing approaches of hotspot detection typically cover specific types of root causes. As one example, a simulation-based approach is directed to finding lithographic and etch related issues. In this regard, such a simulation-based approach may have high accuracy when the issue is relevant to its deployed physical models, and on the condition that the user has high quality models. However, simulation-based approaches may be less able to detect other types of hotspots because the unknown root cause has not yet been modeled well. Another approach to hotspot detection is the Machine Learning (ML)-based supervised models, where known hotspot and non-hotspot patterns are used for training/building the ML model to be used afterwards in prediction of new hotspots. The challenge with the supervised ML approach is the need to compromise between maximizing the hit rate (e.g., finding all potential hotspots) and minimizing the false alarm rate (e.g., reduce the overhead of false positives).

Still another approach comprises clustering of the generated feature vectors of the known hotspots and non-hotspots in order to find the optimum clustering settings to separate the hotspots from non-hotspots in different clusters (e.g., groups). Thereafter, the same tuned clustering settings may be used to detect the potential new patterns that will be clustered with the known hotspots. However, the clustering approach may necessitate many iterations to find the optimum clustering settings, may include coarse tuning of the hit rate and the false alarm rates, and may include only one global setting to fit all hotspots similarly.

Thus, in one or some embodiments, a separation distance (or other measure of closeness) between feature vectors may be used to detect hotspots. Determining separation distance may identify hotspots (interchangeably termed HS) from a variety of root causes (including those root causes that are not well known) in a more efficient manner (e.g., with fewer iterations). A feature vector is one example representation of parts, such as points of interest, of the layout design. The feature vector may comprise a numerical representation of the parts of the layout design. More specifically, the feature vector may comprise an n-dimensional data structure, such as disclosed in PCT Application No. PCT/US2019/049066 entitled “Semiconductor Layout Context Around A Point Of Interest”, attorney docket no. 2019P15420WO, US Patent Application Publication No. 2018/0330493 A1, or US Patent Application Publication No. 2013/0219216 A1, each of which are incorporated by reference herein in their entirety. Thus, in one or some embodiments, the n-dimensional feature vector may include ‘n’ number of separate features (thus, with ‘n’ number of different values) as describing the point of interest. The feature vector may be generated by convolving a set of kernels (e.g., a set of 2-D images) with a representation of the layout design (e.g., a grid). Specifically, the feature vector may include a set of values, with each value resulting from convolution of a respective kernel in the set with a part of the grid (or other representation of the layout design). For example, a respective set of kernels may comprise a predetermined number, such as at least 2 kernels, at least 3 kernels, at least 4 kernels, at least 5 kernels, at least 10 kernels, at least 15 kernels, at least 20 kernels, at least 25 kernels, at least 30 kernels, at least 40 kernels, at least 50 kernels, etc. The convolution of the set of kernels results in the set of values for the feature vector (e.g., for a set of kernels having a first kernel, a second kernel, and a third kernel, convolution of the first kernel with the grid results in a first value, convolution of the second kernel with the grid results in a second value, and convolution of the third kernel with the grid results in a third value). In this regard, the feature vector may comprise an n-dimensional data structure, with each dimension in the n-dimensional structure comprising a numerical representation of one aspect of the part or point or interest in the layout design.

As discussed in more detail below, two or more feature vectors may be compared relative to one another. Various manners of comparison are contemplated. Distance calculation, such as a Euclidean distance calculation, is one example of a comparison of two or more feature vectors relative to one another. In this regard, distance (such as Euclidian distance) may provide an indicator of closeness or separation between two or more feature vectors, and in turn may be used in order to identify hotspots and/or non-hotspots that would otherwise not be identified and/or not be identified as efficiently. Other calculations of distances or other comparisons are contemplated.

As discussed above, the feature vector may comprise an n-dimensional feature vector. In such an instance, the distance is calculated between part or all of a first n-dimensional feature vector and part or all of a second n-dimensional feature vector(s). For example, the overall distance between the first feature vector and the second feature vector may be based on distances between the values of the different dimensions of feature vectors, such as based on a distance between a value for the first dimension of the first feature vector and a value for the first dimension of the second feature vector, a distance between a value for the second dimension of the first feature vector and a value for the second dimension of the second feature vector, etc. In one or some embodiments, one, some, or all of the dimensions in the n-dimensional feature vector may be normalized prior to calculation of the distance so that dimension(s) with higher values do not dominate. Alternatively, or in addition, a subset of dimensions of the n-dimensional feature vector may be used to calculate the distance and/or one, some, or all of the dimensions may be weighted prior to the distance calculation. For example, a subset of the n-dimensions, such as m-dimensions (where m<n) of the feature vector may be used for the distance calculation. The selection of the subset of the n-dimensions may be based on training/analysis, as discussed further below.

The calculated distances may be analyzed in order to determine one or more thresholds (interchangeably termed separation distance thresholds), which may thereafter be used for subsequent hotspot detection. Various types of analysis are contemplated, such as performing mathematical analysis of the distances (e.g., plotting the distances in a scatter plot, with the scatter plot analyzed based on predefined metrics, such as false alarm rate or hit rate, in order to determine the one or more thresholds) or performing the machine learning (such as semi-supervised machine learning) using the distances.

For example, the semi-supervised approach may use the feature vectors to calculate the distance (such as the Euclidean distance or other measure the distance) between one, some or all known hotspots in a training dataset and all other patterns. The quantitative distance may be used during the training/analysis phase to detect the optimum distance gap (based on one or more metrics) to separate hotspots from non-hotspots, and may be performed in one iteration. Per every known hotspot in the training dataset, the nearest non-hotspot (or nearest predetermined number of non-hotspots) may be specified and the separation distance may be used to the nearest non-hotspot (or the nearest predetermined number of non-hotspots) in classifying any pattern within the vicinity of the known hotspot and far enough from known non-hotspot(s) to be a potential hotspot. This may be performed for all hotspots in the training dataset in order to determine the one or more thresholds. The thresholds may, in effect, be used to delineate potential hotspots from non-hotspots based on distance from a known hotspot.

In one or some embodiments, the distance threshold may comprise the smallest separation distance, and may be used globally on all hotspots (e.g., a single distance threshold used for subsequent comparison with known hotspots). Alternatively, multiple thresholds may be generated, such as being customized for some or every hotspot in the training dataset. For example, the distance thresholds may comprise a look-up table (e.g., correlating a series of points in the scatter plot with corresponding distance thresholds), a curve, or a piecewise linear function.

Merely by way of example, a training dataset may include 1,000 hotspots, with one, some, or each of the 1,000 hotspots including a specific threshold (e.g., each hotspots has a different threshold; some hotspots have the same threshold; or all hotspots have the same threshold). A new dataset (corresponding to a layout under consideration) may include a plurality of indeterminate spots (e.g., all of the spots in the new dataset may be indeterminate; or some of the spots in the new dataset may be indeterminate). For a respective spot in the layout under consideration, a distance to a closest known hotspot in the training dataset may be calculated. If the distance calculated is less than the threshold associated with the closest known hotspot in the training dataset, the respective spot in the layout under consideration may be identified as a potential hotspot.

Thus, in one implementation, the distances between one, some, or all of the hotspots from the training dataset to the data (such as one, some, or each of the spots) in the new layout may be calculated. The calculated distances may be placed in 2D array (e.g., rows correlate to the training hotspot data and columns correlate to new data). Scanning through the columns may determine the nearest training hotspot to one, some, or each of the new data in the new layout. Alternatively, or in addition, scanning through the rows may identify the new potential hotspots nearest to the training hotspots in the new layout data. Thus, while scanning in the rows and the columns, the order of known hotspots in the rows may be identify. In this way, search criteria may be set based on the tailored threshold per known hotspot. Various additional data may be generated for output, including a row index to track which is close to which, thereby recording the training hotspot popularity in the new layout.

Further, the one or more metrics may be used to determine the threshold(s) and may comprise one or both of: (i) a number or a percentage of false alarms; or (ii) a number of potential hotspots to be inspected. With regard to (i), false alarms may comprise designating a spot as a potential hotspot when, in reality, the spot is a non-hotspot. Typically, the greater the distance threshold, the higher the number or percentage of false alarms. With regard to (ii), after identifying potential hotspots, the potential hotspots may be subject to further analysis (e.g., modification of sections of the layout associated with the potential hotspots in order to reduce the likelihood of defects in the sections of the layout. In the event that a certain number (or a certain range) of potential hotspots is expected for further analysis, the threshold(s) may be selected in order to provide that certain number (or certain range), as discussed further below.

Thus, after training and analysis, the one or more thresholds may be used to identify potential hotspots and/or non-hotspots in a new layout. Specifically, the new layout may include: a set of known hotspots; a set of known non-hotspots; and a set of indeterminate spots (e.g., potential hotspots or potential non-hotspots). Distances may be calculated between the indeterminate spots and the closest hotspot (or closets set of hotspots) and/or between the indeterminate spots and the closest non-hotspot (or closets set of non-hotspots). The distances may be compared with the one or more thresholds in order to identify one, some, or all of the indeterminate spots as potential hotspots (and thus potentially subject to further analysis) in the new layout.

In particular, identifying candidate hotspots may be based on one or both of distance to a known hotspot (e.g., if the candidate is within a ring centered at the known hotspot) and or distance to a known non-hotspot (e.g., if the candidate is outside of a ring centered at the known non-hotspot). As such, in one or some embodiments, the separation distance threshold may be used to determine whether a candidate is designated as a potential hotspot based on distance from known hotspot(s). Alternatively, the separation distance threshold may be used to determine whether a candidate is designated as a potential hotspot based on distance away from known non-hotspot(s). Still alternatively, separation distance thresholds from both known hotspots and known non-hotspots may be used. In particular, potential candidates may be ranked based on closeness to one or both of the known hotspots or the known. The ranking may be based on one or both of: (i) whether the potential candidate is within the distance threshold to the known hotspot(s) and/or within the distance threshold to the known non-hotspot(s). As merely one example, four categories of ranking may include in order of higher rank: (1) within the distance threshold to the known hotspot(s) and outside of the distance threshold to the known non-hotspot(s); (2) within the distance threshold to the known hotspot(s) and within the distance threshold to the known non-hotspot(s); (3) outside the distance threshold to the known hotspot(s) and outside of the distance threshold to the known non-hotspot(s); and (4) outside the distance threshold to the known hotspot(s) and within the distance threshold to the known non-hotspot(s). Alternatively, or in addition, ranking may be based on separation distance from one or both of the known hotspot(s) and/or known non-hotspot(s). For example, a closer distance to known hotspot(s) and further distance from known non-hotspot(s) may result in higher ranking.

As merely one example, responsive to a spot in the new layout whose distance to the nearest known hotspot is less than the threshold(s) and/or whose distance to the nearest known non-hotspot is greater than the threshold(s), the spot may be designated as a potential hotspot. As another example, responsive to the spot in the new layout whose average distance to a predetermined number nearest known hotspots (e.g., the average of the distances to the three nearest known hotspots) is less than the threshold(s) and/or whose average distance to a predetermined number nearest known non-hotspots (e.g., the average of the distances to the three nearest known non-hotspots) is greater than the threshold, the spot may be designated as a potential hotspot. Thus, during a prediction phase, separation distance(s) may be calculated between the known hotspots and one, some, or all new patterns, and the calculated separation distance(s) may be used as threshold(s) to detect the new potential hotspots. The new potential hotspots may be ordered based on distance closeness to the known hotspots, and the distance metric may be used as confidence ranking of those new patterns for further analysis.

As such, the methodology may be used in a variety of contexts including in any one, any combination, or all of: training/analysis; semi-supervised hotspot detection; inspection candidates; or litho-friendly design (LFD) sampling. With regard to training/analysis, the training dataset may comprise known hotspots and known non-hotspots. The objective for training/analysis comprises: assessing and comparing effectiveness of the defined feature vector to separate hotspots and/or non-hotspots; and/or tun optimum threshold of distance for HS detection or sampling application. The user-specified parameters comprise feature vector candidates (e.g., slices of feature vectors or different density settings). Finally, the output of training/analysis may include any one, any combination, or all of: visual analysis by graphs (such as scatter plot graphs); equivalent metrics for benchmark; identifying optimum feature vectors (e.g., identify one or more dimensions in the n-dimensional feature vector of relevance and/or weight various dimensions in the n-dimensional feature vector); or identify optimum threshold (e.g., based on one or more metrics such as one or both of false alarm rate or number of hits).

With regard to the semi-supervised approach, the inputs may comprise the training dataset including known hotspots and known non-hotspots and the new layout (which may include new unlabeled spots). The objective may comprise one or both of: selecting a minimum amount of new patterns as potential hotspots (e.g., a minimum number of potential hotspots for further analysis); or multi-objective optimization for hit rate and/or false alarm rate. The user specified parameters may include the optimal threshold, extracted from the analysis mode discussed above and based on a designated acceptable false alarm rate. Further, the output of the semi-supervised hotspot detection may include one or both of: potential new hotspots (which may be ranked by closeness to a known hotspot or to a set of known hotspots); or the feature vectors that are far from both hotspots and non-hotspots. In this regard, the semi-supervised approach may have an advantage of using a small set of hotspot samples to simultaneously control the trade-off of high hit rate and low false alarm rate. Thus, the semi-supervised approach may start from the known hotspots as the pivots and rank the new patterns based on similarity closeness to the hotspots, accordingly detecting the potential hotspots within a confidence limit.

With regard to the inspection candidates approach, the inputs may comprise the training dataset including known hotspots and the new layout (which may include new unlabeled spots). The objective may comprise one or both of: selecting the specific amount of new feature vectors for inspection; and the criteria for more similarity to known hotspots. The user specified parameters may include the percentage of potential hotspots (e.g., new feature vectors) for further inspection. As discussed above, the spots identified as potential hotspots may be subject to further analysis. Given a constraint in the inspection capacity of the number of potential hotspots (e.g., limit the number to no more than 1,000), the thresholds may be selected. Further, the output of the inspection candidates approach comprises a list of selected feature vectors and/or coordinates, which may be ranked by closeness to known hotspots and/or to known non-hotspots.

With regard to the LFD sampling approach, the inputs may comprise the training dataset including known hotspots and known non-hotspots. The objective may comprise one or both of: sub-sampling of part or all of the non-hotspot domain for machine learned-LFD; and the criteria for an improved approach than unsupervised clustering. The user specified parameters may include grouping criteria of the feature vectors (e.g., dividing the feature vectors by closeness level into a predetermined number of groups, such as 10 groups). Further, the output of the inspection candidates approach comprises a list of selected feature vectors and/or chords per large group; and clustering step for representative selection of feature vectors.

Thus, using the separation distance for determining one or more thresholds for hotspot detection may result in one or more advantages, such as efficiency and user-friendly flow. In one or some embodiments, a single iteration may generate the one or more thresholds, where all calculations and analysis may be performed in the background without need for user tuning for the optimum settings. Another advantage comprises multi-objective optimization, such as both of hit rate and false alarm rate. As discussed in more detail below, the distance calculation from the known hotspots results in a hotspot centric analysis, namely placing the known hotspots as the center of the clusters (e.g., since the distance is calculated from the known hotspots). This hotspot-centric analysis assists in minimizing the clustering of non-hotspots as false positives and maximizes the detection of true hotspots. This is in contrast to conventional clustering approaches, which do not use the known hotspots as the centers of clusters.

Another advantage comprises optional fine tuning and tailoring per every hotspot. Specifically, the quantitative separation distance may be customized per every known hotspot to adapt to its unique feature vector in the multi-dimensional space. Still another advantage comprises ranking of new potential hotspots in straightforward and explainable approach using the distance closeness to known hotspots, with the ranking indicative of a confidence level for the predicted results. Finally, another advantage includes no need to re-build or re-calibrate a new model when new known hotspots are added to the library. This is in contrast to other approaches, which require redoing the training phase to include the new introduced patterns, thereby impacting the previous regression prediction results. In contrast, the disclosed separation distance based approach may add new hotspots and consider its independent separation distance to other points in a customized mode.

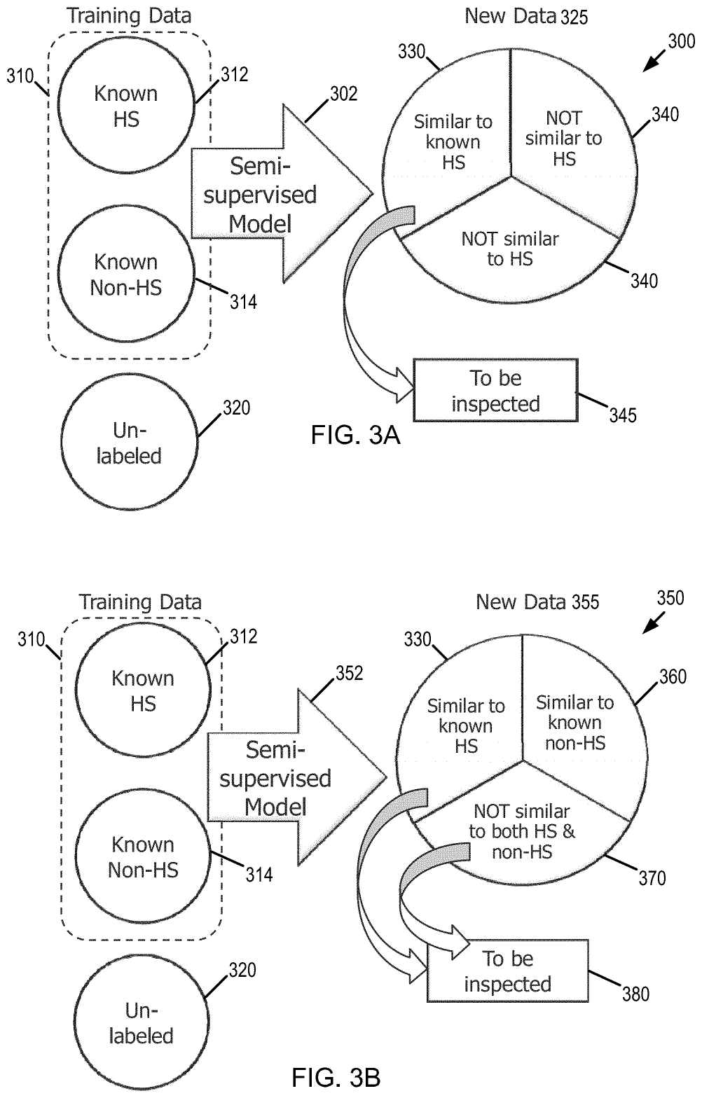

Referring to back the figures, FIGS. 3A-B comprise two illustrations 300, 350 of semi-supervised feature vector classification. Specifically, training data 310 may include known hotspots (HS) 312 and known non-hotspots (NETS) 314. As discussed in more detail below, various methods use the training data 310 in order to generate the semi-supervised model 302. As one example, a semi-supervised machine learning (ML) methodology may use a small set of known samples for the training data 310 (which includes the known HS 312 and known NETS 314) and excludes the unlabeled data 320. Thereafter, the semi-supervised model 302, 352 may be applied to new data 325, 355, which may comprise feature vectors associated with a layout under examination. Specifically, the layout under examination may include known HS, known NETS, and indeterminate spots. After training, the semi-supervised model 302 may be applied to the new data 325 in FIG. 3A in order to identify the subset of the new data that is similar to known HS (330) and the subset of the new data that is not similar to known HS (340). In this way, the subset of the new data that is similar to known HS (330) may be subject to further inspection (345). Alternatively, the semi-supervised model 352 may be applied to the new data 355 in FIG. 3B in order to identify the subset of the new data that is similar to known HS (330), the subset of the new data that is similar to known NHS (360), and the subset of the new data that is not similar to both HS and NHS (370), with further inspection 380 being performed for the subset of the new data that is similar to known HS (330) and the subset of the new data that is not similar to both HS and NHS (370). In this way, training for the semi-supervised model 302, 352 may be on a smaller set of training data, may be performed more efficiently (such as in a single iteration), and may identify hotspots that have an unknown root cause (but are designated as close to other known hotspots).

As discussed above, training to generate the one or more thresholds, and applying the one or more thresholds may be hotspot-centric. For example, training, using a dataset of known hotspots and known non-hotspots, may determine distances from a respective known hotspot to one or more other known hotspots, and to one or more known non-hotspots. Thereafter, the determined distances may be used to determine the one or more thresholds. Further, application of the thresholds may be hotspot-centric. Specifically, the threshold(s) may be centered on known hotspots in the layout under examination to identify indeterminate spots that are within the threshold(s) from the known hotspots. This is in contrast to conventional cluster-based analysis, which define clusters (e.g., clusters based on N-dimensional feature vectors) and thereafter apply the clusters to the layout under examination (e.g., a specific cluster includes a known hotspot; other indeterminate spots in the specific cluster are identified as potential hotspots by virtue of being in the same cluster).

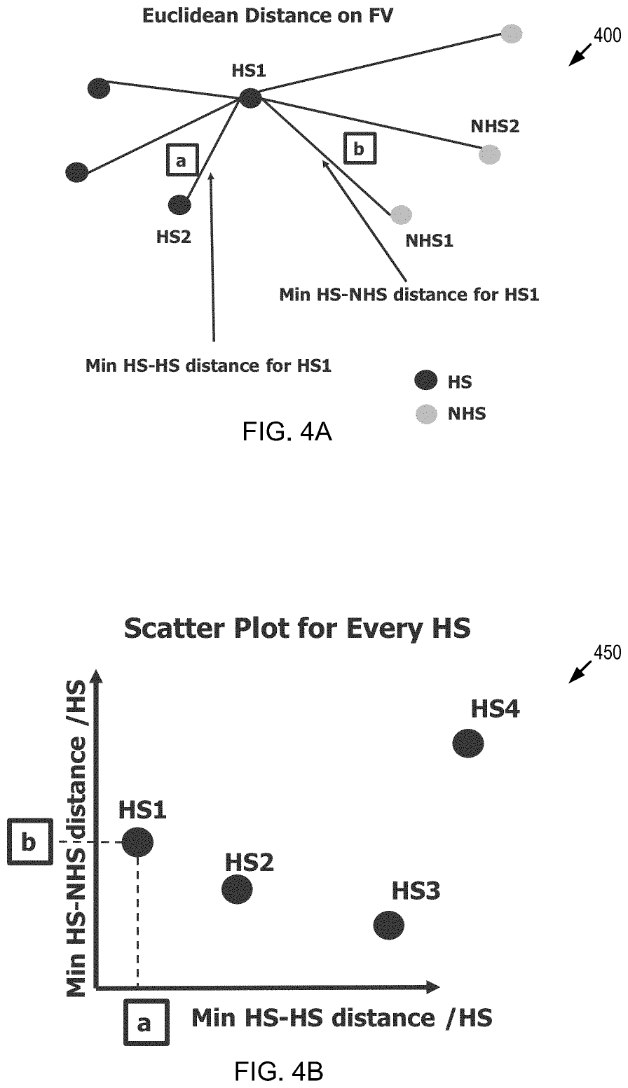

FIG. 4A is an illustration 400 of calculating Euclidian distance for a feature vector (FV). As discussed above, the feature vector may be N-dimensional. For purposes of simplicity, FIG. 4A illustrates a 2-dimensional feature vector; however, higher dimensional feature vectors are contemplated. As shown, the distance for hotspot 1 (HS1) to other hotspots, such as hotspot 2 (HS2) are calculated. In particular, “a” is distance calculated between HS1 and HS2, which is designated as the minimum hotspot/hotspot (HS-HS) distance for HSI. Further, the distance for hotspot 1 (HS1) to other non-hotspots, such as non-hotspot 1 (NHS1) are calculated. In particular, “b” is distance calculated between HS1 and NHS1, which is designated as the minimum hotspot/non-hotspot (HS-NHS) distance for HSI. FIG. Thus, FIG. 4A illustrates the minimum HS-HS distance and minimum HS-NHS distance indicating the closest hotspot and closest non-hotspot to the respective hotspot under examination. Alternatively, for a respective hotspot, distance to a set of close hotspots and to a set of close non-hotspots may be calculated. For example, distances may be calculated from HS1 to the three closest hotspots and may be calculated from HS1 to the three closest non-hotspots. The distances may be averaged to calculate an averaged minimum HS-HS distance and an averaged minimum HS-NHS distance.

FIG. 4B illustrates a scatter plot 450, plotting the minimum HS-HS distance per HS versus the minimum HS-NHS distance per HS. As shown, the plot for HS1 is based on the value of “a” (illustrated in FIG. 4A) for the minimum HS-HS distance for HS1 and the value of “b” (illustrated in FIG. 4A) for the minimum HS-NHS distance for HS1. Scatter plot 450 also illustrates the points for hotspot2 (HS2), hotspot3 (HS3), and hotspot4 (HS4). Alternatively, the scatter plot may plot different types of distances, such as the averaged minimum HS-HS distance versus the averaged minimum HS-NHS distance for a respective hotspot.

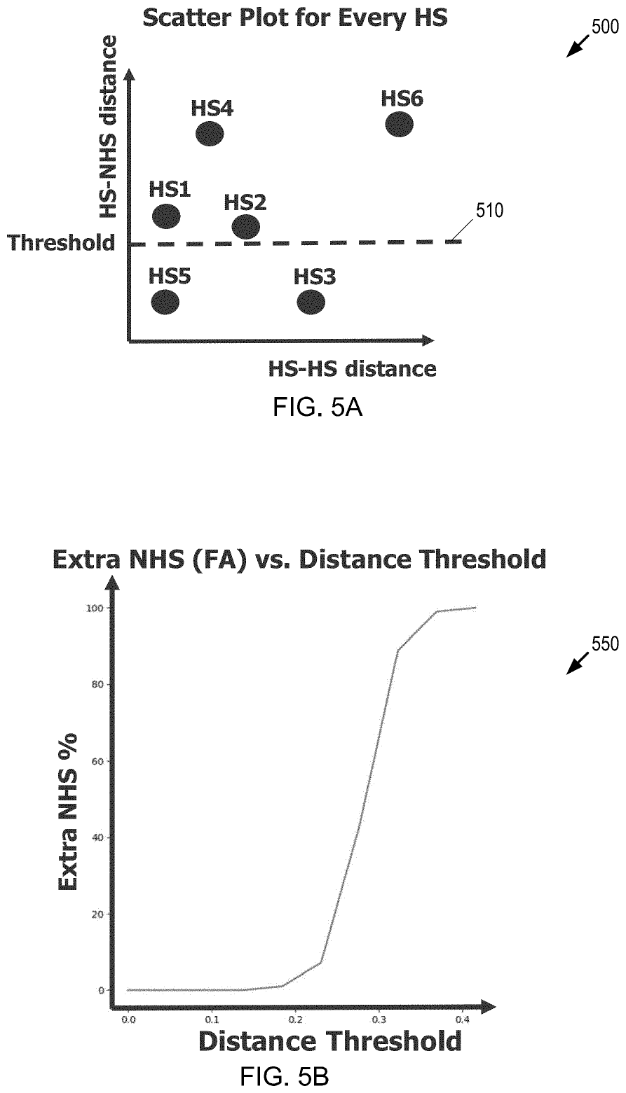

As discussed above, the distances calculated may be used to determine one or more thresholds. In particular, one or more metrics, such as false alarm rate and/or hit rate, may be used to analyze the distances calculated in order to determine the one or more thresholds. For example, a scatter plot, such as 500 illustrated in FIG. 5A, may plot the distances for some or all of the hotspots in the training dataset and may be analyzed to identify the one or more thresholds. As shown in FIG. 5A, the threshold is a line 510. Though, it is contemplated that the threshold may be a curve, piece-wise linear, or based on a look-up table. Further, in one or some embodiments, the threshold(s) may be dependent on the type of hotspot. For example, a first type of hotspot may have a first threshold (or a first set of thresholds) and a second type of hotspot may have a second threshold (or a second set of thresholds).

Alternatively, or in addition, the threshold(s) may be dependent on the type of application. A first example application comprises hotspot detection. Specifically, in order to identify data in a new layout that is close to the known hotspot, the threshold may be set based on the training step, with the new potential hotspots in the new layout output based on the identified hit count or percentage. In particular, the set threshold in the training step may be based on a target separation value between known hotspots and known non-hotspots or a target failure rate/false alarm rate . As merely one example criteria, the threshold may be set to find new potential hotspots in the new layout that are close to known hotspots in the training dataset but select a maximum of 1% of the known non-hotspots in the training dataset as within the distance threshold from known hotspots in the new layout. Known non-hotspots being identified as potential hotspots may be referred to as false alarms, and the rate of such false alarm determinations may be referred to as a failure rate (e.g., as measured as a % of the total known non-hotspots misidentified using the determined distance threshold(s)).

A second application comprises an SEM limited budget hotspot selection. This is similar to the first example application of the hotspot detection; however, the threshold is not fixed. Rather, a maximum predetermined number (e.g., 5,000) of new potential hotspots in the new layout are designated for SEM hotspot validation. In such an example, the percentage of the needed maximum predetermined number within the total count of spots in the new layout is calculated. In turn, the percentage is used to calculate the equivalent needed threshold that satisfies that count or percentage. Thus, the selected new potential hotspots may be considered the closest new data to known hotspots. As such, the threshold is set to identify no more than a limited, predetermined, or maximum number of potential hotspots in the new layout.

A third application comprises down-sampling based on distance criteria, with the objective to down-sample the whole new dataset for a downstream application (e.g. a ML model input or other similar application). All the data in the new layout may be ordered based on closeness to known hotspots in the training dataset. Thereafter, the array of threshold values may be calculated that may lead to binning of the data in the new layout into defined number of buckets. Depending on the sampling technique, the buckets may be equally-sized buckets or equally distanced to specify the equivalent array of threshold values.

Still alternatively, the threshold(s) may be dependent on different process parameters. As such, any one, any combination, or all of the following may be used to select different thresholds: type of hotspot; type of application; or type of process parameters.

In effect, the threshold(s) may be considered multi-dimensional bubbles centered at one, some, or all of the hotspots in the training dataset, thereby defining closeness to the respective hotspots and separateness from the non-hotspots. In practice, the training dataset may include at least one thousand hotspots and non-hotspots, at least ten thousand hotspots and non-hotspots, or more. As discussed above, one or more metrics, such as false alarm percentage or number of spots to be inspect, may be used to determine the threshold(s). In particular, a user may set the false alarm percentage (such as a maximum of 1%) or number of spots to inspect (such as a maximum of 1,000). An optimization function may estimate the threshold(s), compare the threshold(s) against the dataset to generate the statistics (e.g., applying potential threshold(s) to the training dataset to determine a false alarm percentage or a number of hits), compare the statistics with the metrics (e.g., compare the false alarm percentage determined for the potential threshold(s) with the user-defined false alarm percentage), and adjust the threshold(s) accordingly (e.g., if the false alarm percentage determined for the potential threshold(s) is greater than the user-defined false alarm percentage, reduce the potential threshold(s) in order to reduce the false alarm percentage). Thus, determination of the threshold(s) may use an optimization function for the scatter plot to select the threshold(s) based on the one or more metrics. In this way, the threshold(s) may be indicative of optimal separation distance(s) for later use in prediction.

Referring back to FIG. 5A, line 510 may be applied in order to identify in a layout under examination, whether indeterminate spots are subject to further inspection. For example, line 510 indicates that if the minimum distance from an indeterminate spot to a known non-hotspot in the layout under examination is greater than threshold as indicated by line 510, then the indeterminate spot is designated as a potential hotspot. In this regard, HS5 is not considered a hotspot (and is designated as a non-hotspot, which is a false positive). Likewise, HS3 is not considered a hotspot.

As shown in FIG. 5A, spots may be compared to the threshold on an individual basis. As one example, an indeterminate spot may be compared with the threshold in order to determine whether it is a potential hotspot (e.g., indeterminate spot to nearest hotspot and . Alternatively, indeterminate spots may be compared on a group basis, such as a group of multiple indeterminate spots (e.g., a set of multiple indeterminate spots that are within a predetermined distance from one another may be grouped together) may be compared with a group of known hotspots and with a group of known non-hotspots.

FIG. 5B illustrates a graph 550 of the distance threshold versus designation of extra non-hotspots (false alarms). As shown, as the distance threshold increases, the percentage of extra NHS increases. Thus, increasing the threshold results in a higher false alarm rate, but captures more new potential hotspots.

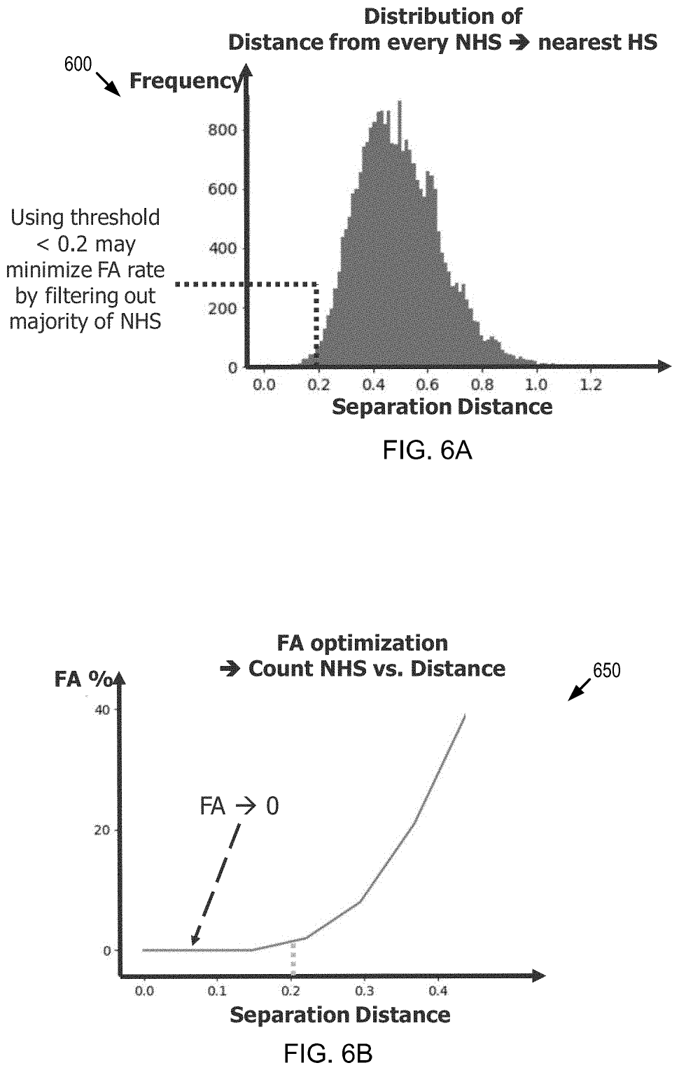

FIG. 6A illustrates a graph 600 of separation distance versus frequency, with the graph showing a distribution of distance from every non-hotspot to the nearest hotspot. As shown, the higher the separation distance, the higher the number of non-hotspots to the nearest hotspot. This correlates to increasing the separation distance threshold resulting in a higher false alarm rate. As shown in FIG. 6A, a threshold <0.2 may minimize the false alarm rate by filtering out a majority of non-hotspots.

FIG. 6B illustrates a graph 650 of the separation distance versus the false alarm rate, which may assist in determining false alarm rate optimization by counting non-hotspots subject to false alarm versus distance. A sharp or noticeable bend in the curve, such as that illustrated in graph 650, may provide a basis to determine the separation distance threshold. Alternatively, absent a noticeable bend, the user may specify the false alarm percentage, and select the separation distance threshold accordingly. Alternatively, or in addition, the downstream application may determine the number of candidates for further processing (e.g., the hit rate). For example, a downstream application may examine the candidates for potential revision of the design layout. Due to constraints in the downstream processing, the number of candidates may be limited to a predetermined number. Selecting the threshold so that, when applied, will limit the number of candidates to approximately the predetermined number may, in effect, down-sample the candidates for further processing. Further processing may include analysis of the candidates for potential correction or for performing supervised machine learning. Alternatively, or in addition, the candidates for further processing may be ranked, such as ranked based on distance from a known hotspot, with the ranking indicative of a confidence level associated with a respective candidate.

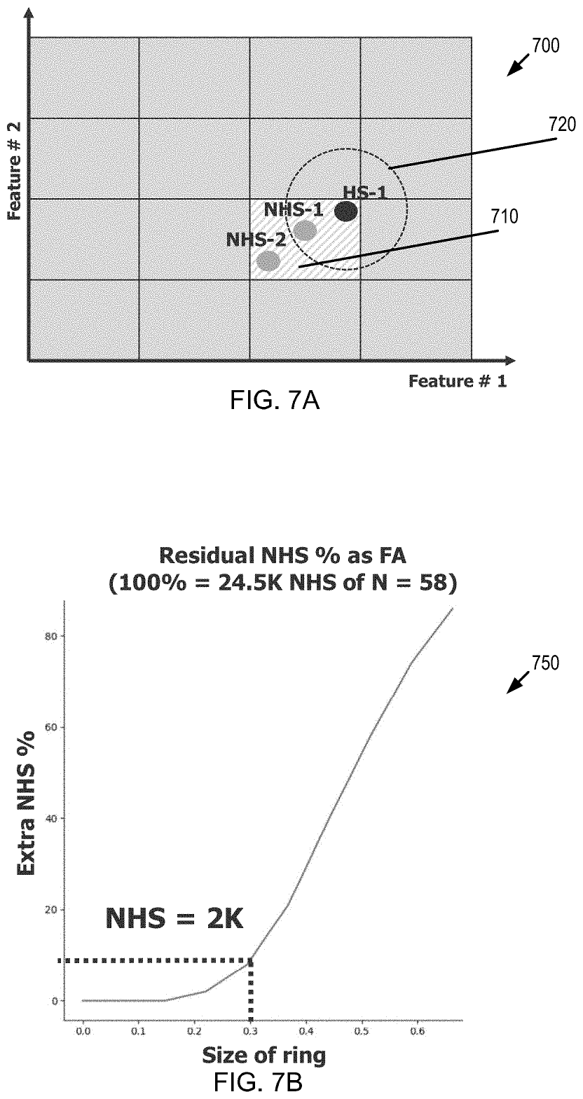

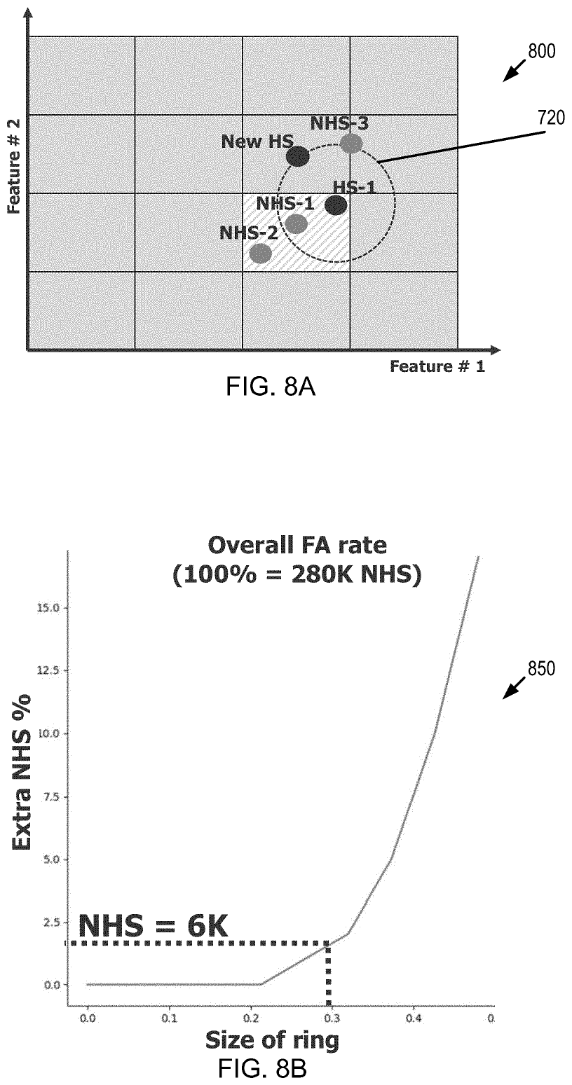

After training, the threshold(s) may be applied to a layout under examination in one of several ways. In one or some embodiments, the threshold(s) may be applied in combination with one or more hotspot detection techniques in order to identify candidates for further examination, such as illustrated in FIGS. 7A-B. Alternatively, the threshold(s) may solely be applied to identify candidate for further examination, such as illustrated in FIGS. 8A-B. For example, FIGS. 7A-B illustrate a sequential application of techniques to identify candidates, including first performing bucketing and thereafter applying the threshold(s). Specifically, FIG. 7A is a graph 700 of feature #1 versus feature #2. As discussed above, feature vectors may be n-dimensional. For purposes of simplicity, the graph 700 depicted in FIG. 7 is of a 2-dimensional feature vector, with feature #1 and feature #2. Higher numbers of n-dimensional feature vectors are contemplated. As one example, a 3-dimensional feature vector may be depicted graphically 3-dimensions, with clusters being 3-dimensional boxes within 3-D space. As another example, a 4-dimensional feature vector may be depicted in 4-dimensions, with clusters likewise being depicted in 4-dimensions (and so on). Clustering of the dimensional space (such as into 2-D clusters, 3-D clusters, 4-D clusters, etc.) may be performed in a variety of ways. As merely one example, PCT application No. PCT/US2020/041153 entitled “Hyperspace-Based Processing Of Datasets For Electronic Design Automation (EDA) Applications”, attorney docket no. 2020P07963WO, incorporated by reference in its entirety, discloses quantizing transformed feature spaces with hyperboxes in order to process, classify, or otherwise analyze datasets through the quantization. The hyperboxes generated may represent a given cluster or a given classification unit in a transformed feature space for use in hotspot detection. One representation of the clustering is illustrated by the grid shown in FIG. 7A, with cluster 710 as one example cluster. In order to first perform bucketing, the buckets in which a hotspot are identified. For example, hotspot-1 (HS-1) is depicted in cluster 710, signifying further potential analysis for points non-hotspot-1 (NHS-1) and non-hotspot-2 (NHS-2) within cluster 710. Subsequent to identifying potential candidates within cluster 710, the one or more thresholds may be applied in order to further reduce the candidates for further consideration. In particular, threshold (depicted as ring 720) is centered around HS-1, with only the potential candidates within ring 720 and in cluster 710 considered for further examination. Thus, NHS-1 is considered a candidate for further examination, but NHS-2 is not. Thus, unlike traditional clustering, which may not have a hotspot-centric approach, applying the thresholds, centered on the hotspot identified within the cluster enables a hotspot-centric approach. FIG. 7B is a graph 750 of the size of the ring versus the extra NHS %. As shown, as the size of the ring 720 increases, the extra NHS % increases as well. In this way, the size of the ring 720 may be viewed as performed down-sampling of candidate hotspots.

Similar to FIG. 7A, FIG. 8A is a graph 800 of feature #1 versus feature #2. The clusters depicted in FIG. 8A are merely for comparison. FIG. 8A depicts solely applying the threshold, depicted as ring 720, without clustering to identify candidate hotspots. As shown, ring 720 is centered on HS-1, within which one or more candidate hotspots, such as New HS, may be within (which was missed in the methodology depicted in FIG. 7A). Conversely, NHS-3 identified as a candidate in FIG. 8A is potentially excluded due to bucketing, as illustrated in FIG. 7A. As such, candidate hotspots as depicted in FIG. 8A are not confined within the cluster in which the HS resides. Rather, the candidate hotspots are selected based on whether they are within the threshold. Similar to FIG. 7B, FIG. 8B is a is a graph 850 of the size of the ring versus the extra NHS %. As shown, as the size of the ring 720 increases, the extra NHS % increases as well. The various candidates may further be ranked, such as ranking NHS-1 higher than NHS-3 since NHS-1 is closer to HS-1 than NHS-3.

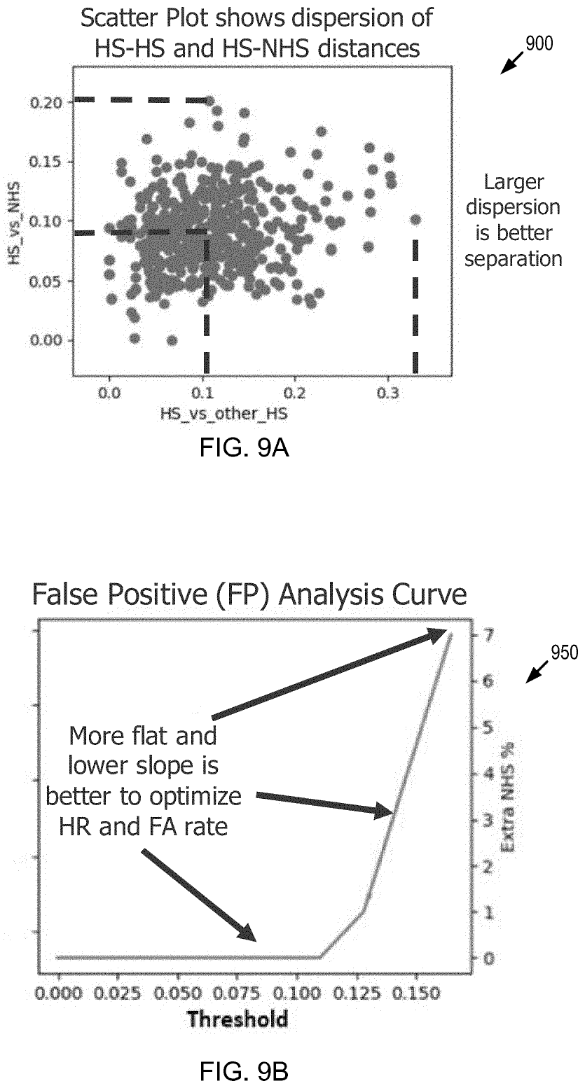

FIG. 9A illustrates a scatter plot 900 of distance from hotspot to another nearest hotspot versus hotspot to another nearest non-hotspot. The scatter plot 900, including a practical implementation with at least thousands or at least millions of plot points, illustrates that dispersion of hotspot-hotspot and hotspot/non-hotspot distances, with larger dispersion indicative of better separation. FIG. 9B is a graph 950 of the distance threshold verse extra NHS percentage, with the curve depicting a false positive analysis curve. As shown, the curve that is flatter and lower slope may be better to optimize the hit rate (HA) and false alarm (FA) rate.

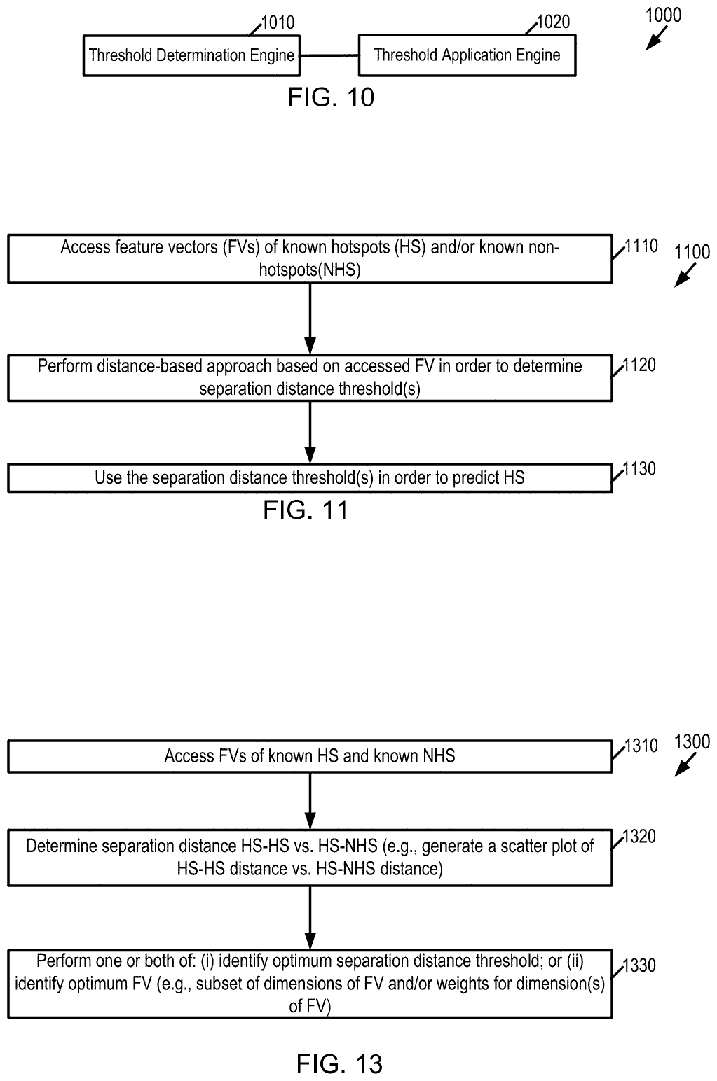

FIG. 10 illustrates a block diagram 1000 of a threshold determination engine 1010 and a threshold application engine 1020. As discussed above, various computing environments are contemplated, such as depicted in FIGS. 1-2. Further, the threshold determination engine 1010 and the threshold application engine 1020 may be part of the same computing unit or may be assigned to different computing units. The threshold determination engine 1010 may be configured to determine the one or more thresholds discussed here. As merely one example, the threshold determination engine 1010 may be configured to perform the semi-supervised machine learning discussed herein and/or the training/analysis discussed here. Further, the threshold application engine 1020 may be configured to apply the one or more thresholds to a variety of contexts. Example applications include hotspot detection, inspection candidates, and LFD sampling. Other example applications are contemplated.

FIG. 11 is a first flow chart 1100 for determining and using separation distance threshold(s). At 1110, feature vectors of known hotspots and known non-hotspots are accessed. At 1120, a distance-based approach is performed based on the accessed feature vectors in order to determine the separation distance threshold(s). At 1130, the separation distance threshold(s) are used in order to predict hotspots.

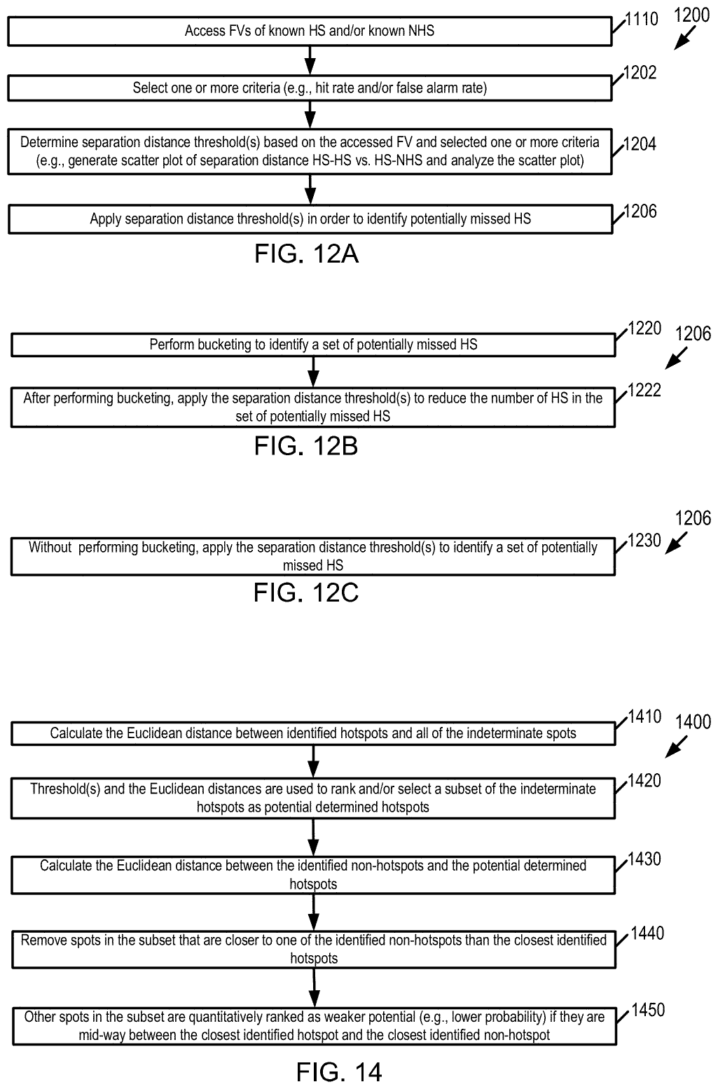

FIG. 12A is a second flow chart 1200 for determining and using separation distance threshold(s). At 1110, feature vectors of known hotspots and known non-hotspots are accessed. At 1202, one or more criteria are selected, such as hit rate and/or false alarm rate. At 1204, the separation distance threshold(s) are determined based on the accessed feature vectors and the selected one or more criteria. As one example, a scatter plot of separation distance HS-HS vs. HS-NHS may be generated and analyzed. At 1206, the separation distance threshold(s) are applied in order to identify potentially missed hotspots.

As discussed above, various applications of the separation distance threshold(s) are contemplated. As one example, the separation distance threshold(s) may be applied in combination with another hotspot detection methodology. For example, FIG. 12B illustrates a first expanded flow diagram for block 1206 of FIG. 12A in which at 1220, bucketing is performed to identify a set of potentially missed hotspots, and at 1222, after performing bucketing, applying the separation distance threshold(s) in order to reduce the number of hotspots in the set of potentially missed hotspots. This is illustrated, for example, in FIGS. 7A-B, discussed above. As another example, the separation distance threshold(s) may be solely applied to identify potential hotspots. For example, FIG. 12C illustrates a second expanded flow diagram for block 1206 of FIG. 12A in which at 1230, without performing bucketing, the separation distance threshold(s) is applied in order to reduce the number of hotspots in the set of potentially missed hotspots. This is illustrated, for example, in FIGS. 8A-B, discussed above.

FIG. 13 is a flow chart 1300 for determining one or both of the optimum separation distance threshold or the optimum feature vector. At 1310, the feature vectors of known HS and known NHS are accessed for the training dataset. At 1320, the separation distance HS-HS vs. HS-NHS is determined. For example, a scatter plot of HS-HS distance vs. HS-NHS distance may be generated. At 1330, one or both of the following may be performed: (i) identify the optimum separation distance threshold(s); or (ii) identify the optimum FV (e.g., subset of dimensions of FV and/or weights for dimension(s) of FV). For example, machine learning may be performed in order to determine the optimum FV, such as the subset of dimensions in the feature vector to perform the distance calculation between feature vectors and/or the weights of for the dimensions in calculating the distance.

As discussed above, after training, the threshold(s) may be applied to a new layout to identify one or more potential hotspots therein. In one or some embodiments, the data for the new layout is entirely composed of indeterminate spots (e.g., spots that have not been identified as a hotspots or a non-hotspot). Alternatively, prior processing (e.g., exact pattern matching) may be used to identify within the new layout hotspots and/or non-hotspots and indeterminate spots. Regardless, the threshold(s) developed with the training dataset may be used in order to identify potential hotspots from the indeterminate spots in the new layout, such as illustrated in the flow chart 1400 in FIG. 14.

At 1410, the Euclidean distance is calculated between the identified hotspots in the training dataset and one, some or all of the indeterminate spots in the new layout. At 1420, threshold(s) from training and the calculated Euclidean distances are used to rank and/or select a subset of the indeterminate hotspots as the potential determined hotspots. In one or some embodiments, the selected subset of the indeterminate hotspots as the potential determined hotspots may used for further processing.

Alternatively, additional analysis may further reduce the number of potential determined hotspots. In particular, at 1430, the Euclidean distance may be calculated between the identified non-hotspots in the training dataset and the potential determined hotspots in the selected subset. At 1440, spots in the subset may be removed that are closer (based on the calculated Euclidian distance) to one of the identified non-hotspots in the training dataset than the closest identified hotspots in the training dataset. In other words, potential determined hotspots in the selected subset may be removed if a respective potential determined hotspot is closer to an identified non-hotspot than the closest identified hotspot.

For example, a particular potential hotspot may be in the subset of the indeterminate hotspots designated as potential hotspots. If the particular potential determined hotspot is closer to a known non-hotspot in the training dataset than a closest known hotspot in the training dataset, the particular potential determined hotspot is removed from the subset of the indeterminate spots so that the particular potential determined hotspot is not included in the potential hotspots for further processing.

At 1450, other spots in the selected subset may be quantitatively ranked as weaker potential (e.g., a lower probability) if they are mid-way between the closest identified hotspot and the closest identified non-hotspot. In this way, the potential determined hotspots may be reduced for further processing.

The following example embodiments of the invention are also disclosed:

### Embodiment 1

A computer-implemented method for identifying hotspots in a design layout under examination, the method comprising:

accessing a training dataset that includes known hotspots and known non-hotspots for a training layout;

for some or all of the known hotspots, determining one or both of a hotspot/hotspot separation between a respective known hotspot or a group of respective hotspots and one or more closest known hotspots or a hotspot/non-hotspot separation between the respective known hotspot or the group of respective hotspots and one or more closest known non-hotspots;

determining, based on one or both of the hotspot/hotspot separation and the hotspot/non-hotspot separation for some or all of the known hotspots, one or more thresholds indicative of a hotspot;

accessing a layout under examination, the layout under examination including indeterminate spots;

for some or all of the indeterminate spots, determining one or both of an indeterminate/hotspot separation between a respective indeterminate spot or a group of respective indeterminate hotspots and one or more closest known hotspots or an indeterminate/non-hotspot separation between the respective indeterminate spot or the group of respective indeterminate hotspots and one or more closest known non-hotspots; and

designating, using the one or more thresholds and one or both of the indeterminate/hotspot separation and the indeterminate/non-hotspot separation, some or all of the indeterminate spots as potential hotspots.

### Embodiment 2

The method of embodiment 1,

wherein the known hotspots and known non-hotspots are represented by feature vectors; and

wherein the hotspot/hotspot separation and the hotspot/non-hotspot separation are determined based on distances calculated between the feature vectors.

### Embodiment 3

The method of any of embodiments 1 and Z2,

wherein the distances are Euclidean distances.

Embodiment 4:
The method of any of embodiments 1-3,

wherein for the some or all of the known hotspots, determining both of:
the hotspot/hotspot separation between the respective known hotspot or the group of respective hotspots and the one or more closest known hotspots; and
the hotspot/non-hotspot separation between the respective known hotspot or the group of respective hotspots and the one or more closest known non-hotspots; and

wherein the one or more thresholds are determined based on both of the hotspot/hotspot separation and the hotspot/non-hotspot separation for the some or all of the known hotspots.

### Embodiment 5

The method of any of embodiments 1-4,

wherein the distances for the hotspot/hotspot separation are calculated between a closest hotspot/hotspot; and

wherein the distances for the hotspot/non-hotspot separation are calculated between a closest hotspot/non-hotspot.

### Embodiment 6

The method of any of embodiments 1-4,

wherein the distances for the hotspot/hotspot separation are calculated by averaging distances between a respective hotspot and a predetermined number of closest hotspots, the predetermined number being greater than 1; and

wherein the distances for the hotspot/non-hotspot separation are calculated by averaging distances between the respective hotspot and the predetermined number of closest hotspots.

### Embodiment 7

The method of any of embodiments 1-4,

wherein determining the hotspot/hotspot separation is between the group of respective hotspots and the one or more closest known hotspots; and

wherein the hotspot/non-hotspot separation is between the group of respective hotspots and the one or more closest known non-hotspots.

### Embodiment 8

The method of any of embodiments 1-7,

wherein the feature vectors comprise n-dimensional feature vector; and further comprising one or both of:
analyzing to determine a subset of m-dimensions of the n-dimensional feature vector (where m<n) to use for calculating the distance between the feature vectors; or
analyzing to determine weights for some or all of dimensions in the n-dimensional feature vector to use for calculating the distance between the feature vectors.

### Embodiment 9

The method of any of embodiments 1-7,

wherein the feature vectors comprise n-dimensional feature vector; and further comprising:
analyzing to determine a subset of m-dimensions of the n-dimensional feature vector (where m<n) to use for calculating the distance between the feature vectors; and
analyzing to determine weights for some or all of dimensions in the n-dimensional feature vector to use for calculating the distance between the feature vectors.

### Embodiment 10

The method of any of embodiments 1-9,

wherein at least some of dimensions of the feature vectors are normalized prior to calculating the Euclidian distance between them.

### Embodiment 11

The method of any of embodiments 1-10,

wherein determining the one or more thresholds indicative of the hotspot is based on a failure alarm rate, when applying the one or more thresholds, in designating hotspots.

### Embodiment 12

The method of any of embodiments 1-11,
wherein determining the one or more thresholds indicative of the hotspot is based on a hit rate, when applying the one or more thresholds, in designating hotspots, the hit rate indicative of a number of designated hotspots.

### Embodiment 13

The method of any of embodiments 1-12,

wherein the hotspot/hotspot separation is determined between the respective known hotspot and a single closest known hotspot;

wherein the hotspot/non-hotspot separation is determined between the respective known hotspot and a single closest known non-hotspot; and

wherein the one or more thresholds are determined based on both of the hotspot/hotspot separation and the hotspot/non-hotspot separation.

### Embodiment 14

The method of any of embodiments 1-13,

wherein for some or all of the indeterminate spots, the indeterminate/hotspot separation is determined between the respective indeterminate spot and a single closest known hotspot; and

wherein the some or all of the indeterminate spots are designated as the potential hotspots based on the one or more thresholds and the indeterminate/hotspot separations.

### Embodiment 15

The method of any of embodiments 1-14,

wherein designating some or all of the indeterminate spots as potential hotspots comprises:

selecting, based on the one or more thresholds and the indeterminate/hotspot separations, a subset of the indeterminate spots as potential determined hotspots; and

designating the potential hotspots from the subset of the indeterminate spots as potential determined hotspots by analyzing the indeterminate/non-hotspot separations for the potential determined hotspots.

### Embodiment 16

The method of any of embodiments 1-15,

wherein designating the potential hotspots from the subset of the indeterminate spots as potential determined hotspots by analyzing the indeterminate/non-hotspot separations for the potential determined hotspots comprises:
determining whether a particular potential determined hotspot is closer to a known non-hotspot than a closest known hotspot; and
responsive to determining that the particular potential determined hotspot is closer to the known non-hotspot than the closest known hotspot, removing the particular potential determined hotspot from the subset of the indeterminate spots so that the particular potential determined hotspot is not included in the potential hotspots for further processing.

### Embodiment 17

The method of any of embodiments 1-16,

wherein determining the one or more thresholds indicative of the hotspot comprises:
generating a scatter plot; and
determining the one or more thresholds based on the scatter plot.

### Embodiment 18

The method of any of embodiments 1-17,

wherein the one or more thresholds are determined based on semi-supervised machine learning.

### Embodiment 19

The method of any of embodiments 1-18,

wherein for the some or all of the indeterminate spots, both of the following are determined:
the indeterminate/hotspot separation between the respective indeterminate spot and the one or more closest known hotspots; and
the indeterminate/non-hotspot separation between the respective indeterminate spot and the one or more closest known non-hotspots; and

wherein the some or all of the indeterminate spots are designated as the potential hotspots based on the one or more thresholds, the indeterminate/hotspot separation, and the indeterminate/non-hotspot separation.

### Embodiment 20

The method of any of embodiments 1-19,

wherein the one or more thresholds comprise a single threshold.

### Embodiment 21

The method of any of embodiments 1-19,

wherein the one or more thresholds are customized for at least some of the known hotspots in the training dataset.

### Embodiment 22

A system comprising:

a processor; and

a non-transitory machine-readable medium comprising instructions that, when executed by the processor, cause a computing system to perform a method according to any of embodiments 1-21.

### Embodiment 23

A non-transitory machine-readable medium comprising instructions that, when executed by a processor, cause a computing system to perform a method according to any of embodiments 1-21.

The above disclosed subject matter is to be considered illustrative, and not restrictive, and the appended claims are intended to cover all such modifications, enhancements, and other embodiments, which fall within the true spirit and scope of the description. Thus, to the maximum extent allowed by law, the scope is to be determined by the broadest permissible interpretation of the following claims and their equivalents, and shall not be restricted or limited by the foregoing detailed description.

1. A computer-implemented method for identifying hotspots in a design layout under examination, the method comprising:
accessing a training dataset that includes known hotspots and known non-hotspots for a training layout;
for some or all of the known hotspots, determining one or both of a hotspot/hotspot separation between a respective known hotspot or a group of respective hotspots and one or more closest known hotspots or a hotspot/non-hotspot separation between the respective known hotspot or the group of respective hotspots and one or more closest known non-hotspots;
determining, based on one or both of the hotspot/hotspot separation and the hotspot/non-hotspot separation for some or all of the known hotspots, one or more thresholds indicative of a hotspot;
accessing a layout under examination, the layout under examination including indeterminate spots;
for some or all of the indeterminate spots, determining one or both of an indeterminate/hotspot separation between a respective indeterminate spot or a group of respective indeterminate hotspots and one or more closest known hotspots or an indeterminate/non-hotspot separation between the respective indeterminate spot or the group of respective indeterminate hotspots and one or more closest known non-hotspots; and
designating, using the one or more thresholds and one or both of the indeterminate/hotspot separation and the indeterminate/non-hotspot separation, some or all of the indeterminate spots as potential hotspots.

2. The method of claim 1, wherein the known hotspots and known non-hotspots are represented by feature vectors; and
wherein the hotspot/hotspot separation and the hotspot/non-hotspot separation are determined based on distances calculated between the feature vectors.

3. The method of claim 2, wherein the distances are Euclidean distances;
wherein for the some or all of the known hotspots, determining both of:
the hotspot/hotspot separation between the respective known hotspot or the group of respective hotspots and the one or more closest known hotspots; and
the hotspot/non-hotspot separation between the respective known hotspot or the group of respective hotspots and the one or more closest known non-hotspots; and
wherein the one or more thresholds are determined based on both of the hotspot/hotspot separation and the hotspot/non-hotspot separation for the some or all of the known hotspots.

4. The method of claim 3, wherein the distances for the hotspot/hotspot separation are calculated between a closest hotspot/hotspot; and
wherein the distances for the hotspot/non-hotspot separation are calculated between a closest hotspot/non-hotspot.

5. The method of claim 3, wherein the distances for the hotspot/hotspot separation are calculated by averaging distances between a respective hotspot and a predetermined number of closest hotspots, the predetermined number being greater than 1; and
wherein the distances for the hotspot/non-hotspot separation are calculated by averaging distances between the respective hotspot and the predetermined number of closest hotspots.

6. The method of claim 3, wherein determining the hotspot/hotspot separation is between the group of respective hotspots and the one or more closest known hotspots; and
wherein the hotspot/non-hotspot separation is between the group of respective hotspots and the one or more closest known non-hotspots.

7. The method of claim 3, wherein the feature vectors comprise n-dimensional feature vector; and
further comprising one or both of:
analyzing to determine a subset of m-dimensions of the n-dimensional feature vector (where m<n) to use for calculating the distance between the feature vectors; or
analyzing to determine weights for some or all of dimensions in the n-dimensional feature vector to use for calculating the distance between the feature vectors.

8. The method of claim 3, wherein the feature vectors comprise n-dimensional feature vector; and
further comprising:
analyzing to determine a subset of m-dimensions of the n-dimensional feature vector (where m<n) to use for calculating the distance between the feature vectors; and
analyzing to determine weights for some or all of dimensions in the n-dimensional feature vector to use for calculating the distance between the feature vectors.

9. The method of claim 3, wherein determining the one or more thresholds indicative of the hotspot is based on a failure alarm rate, when applying the one or more thresholds, in designating hotspots.

10. The method of claim 3, wherein determining the one or more thresholds indicative of the hotspot is based on a hit rate, when applying the one or more thresholds, in designating hotspots, the hit rate indicative of a number of designated hotspots.

11. The method of claim 1, wherein the hotspot/hotspot separation is determined between the respective known hotspot and a single closest known hotspot;
wherein the hotspot/non-hotspot separation is determined between the respective known hotspot and a single closest known non-hotspot; and
wherein the one or more thresholds are determined based on both of the hotspot/hotspot separation and the hotspot/non-hotspot separation.

12. The method of claim 11, wherein for some or all of the indeterminate spots, the indeterminate/hotspot separation is determined between the respective indeterminate spot and a single closest known hotspot; and
wherein the some or all of the indeterminate spots are designated as the potential hotspots based on the one or more thresholds and the indeterminate/hotspot separations.

13. The method of claim 12, wherein designating some or all of the indeterminate spots as potential hotspots comprises:
selecting, based on the one or more thresholds and the indeterminate/hotspot separations, a subset of the indeterminate spots as potential determined hotspots; and
designating the potential hotspots from the subset of the indeterminate spots as potential determined hotspots by analyzing the indeterminate/non-hotspot separations for the potential determined hotspots.

14. The method of claim 13, wherein designating the potential hotspots from the subset of the indeterminate spots as potential determined hotspots by analyzing the indeterminate/non-hotspot separations for the potential determined hotspots comprises:
determining whether a particular potential determined hotspot is closer to a known non-hotspot than a closest known hotspot; and
responsive to determining that the particular potential determined hotspot is closer to the known non-hotspot than the closest known hotspot, removing the particular potential determined hotspot from the subset of the indeterminate spots so that the particular potential determined hotspot is not included in the potential hotspots for further processing.

15. The method of claim 1, wherein for the some or all of the indeterminate spots, both of the following are determined:
the indeterminate/hotspot separation between the respective indeterminate spot and the one or more closest known hotspots; and
the indeterminate/non-hotspot separation between the respective indeterminate spot and the one or more closest known non-hotspots; and
wherein the some or all of the indeterminate spots are designated as the potential hotspots based on the one or more thresholds, the indeterminate/hotspot separation, and the indeterminate/non-hotspot separation.

16. The method of claim 1, wherein the one or more thresholds are customized for at least some of the known hotspots in the training dataset.

17. A non-transitory machine-readable medium comprising instructions that, when executed by a processor, cause a computing system to perform a method comprising:
accessing a training dataset that includes known hotspots and known non-hotspots for a training layout;
for some or all of the known hotspots, determining one or both of a hotspot/hotspot separation between a respective known hotspot or a group of respective hotspots and one or more closest known hotspots or a hotspot/non-hotspot separation between the respective known hotspot or the group of respective hotspots and one or more closest known non-hotspots;
determining, based on one or both of the hotspot/hotspot separation and the hotspot/non-hotspot separation for some or all of the known hotspots, one or more thresholds indicative of a hotspot;
accessing a layout under examination, the layout under examination including indeterminate spots;
for some or all of the indeterminate spots, determining one or both of an indeterminate/hotspot separation between a respective indeterminate spot or a group of respective indeterminate hotspots and one or more closest known hotspots or an indeterminate/non-hotspot separation between the respective indeterminate spot or the group of respective indeterminate hotspots and one or more closest known non-hotspots; and
designating, using the one or more thresholds and one or both of the indeterminate/hotspot separation and the indeterminate/non-hotspot separation, some or all of the indeterminate spots as potential hotspots.

18. The non-transitory machine-readable medium of claim 17, wherein the known hotspots and known non-hotspots are represented by feature vectors; and
wherein the hotspot/hotspot separation and the hotspot/non-hotspot separation are determined based on distances calculated between the feature vectors.

19. The non-transitory machine-readable medium of claim 18, wherein the distances are Euclidean distances;
wherein for the some or all of the known hotspots, determining both of:
the hotspot/hotspot separation between the respective known hotspot or the group of respective hotspots and the one or more closest known hotspots; and
the hotspot/non-hotspot separation between the respective known hotspot or the group of respective hotspots and the one or more closest known non-hotspots; and
wherein the one or more thresholds are determined based on both of the hotspot/hotspot separation and the hotspot/non-hotspot separation for the some or all of the known hotspots.

20. The non-transitory machine-readable medium of claim 19, wherein the distances for the hotspot/hotspot separation are calculated between a closest hotspot/hotspot; and
wherein the distances for the hotspot/non-hotspot separation are calculated between a closest hotspot/non-hotspot.

21. The non-transitory machine-readable medium of claim 19, wherein the distances for the hotspot/hotspot separation are calculated by averaging distances between a respective hotspot and a predetermined number of closest hotspots, the predetermined number being greater than 1; and
wherein the distances for the hotspot/non-hotspot separation are calculated by averaging distances between the respective hotspot and the predetermined number of closest hotspots.

22. The non-transitory machine-readable medium of claim 19, wherein determining the hotspot/hotspot separation is between the group of respective hotspots and the one or more closest known hotspots; and
wherein the hotspot/non-hotspot separation is between the group of respective hotspots and the one or more closest known non-hotspots.

23. The non-transitory machine-readable medium of claim 19, wherein the feature vectors comprise n-dimensional feature vector; and
further comprising one or both of:
analyzing to determine a subset of m-dimensions of the n-dimensional feature vector (where m<n) to use for calculating the distance between the feature vectors; or
analyzing to determine weights for some or all of dimensions in the n-dimensional feature vector to use for calculating the distance between the feature vectors.

24. The non-transitory machine-readable medium of claim 19, wherein the feature vectors comprise n-dimensional feature vector; and
further comprising:
analyzing to determine a subset of m-dimensions of the n-dimensional feature vector (where m<n) to use for calculating the distance between the feature vectors; and
analyzing to determine weights for some or all of dimensions in the n-dimensional feature vector to use for calculating the distance between the feature vectors.

25. The non-transitory machine-readable medium of claim 19, wherein determining the one or more thresholds indicative of the hotspot is based on a failure alarm rate, when applying the one or more thresholds, in designating hotspots.

26. The non-transitory machine-readable medium of claim 19, wherein determining the one or more thresholds indicative of the hotspot is based on a hit rate, when applying the one or more thresholds, in designating hotspots, the hit rate indicative of a number of designated hotspots.

27. The non-transitory machine-readable medium of claim 17, wherein the hotspot/hotspot separation is determined between the respective known hotspot and a single closest known hotspot;
wherein the hotspot/non-hotspot separation is determined between the respective known hotspot and a single closest known non-hotspot; and
wherein the one or more thresholds are determined based on both of the hotspot/hotspot separation and the hotspot/non-hotspot separation.

28. The non-transitory machine-readable medium of claim 27, wherein for some or all of the indeterminate spots, the indeterminate/hotspot separation is determined between the respective indeterminate spot and a single closest known hotspot; and
wherein the some or all of the indeterminate spots are designated as the potential hotspots based on the one or more thresholds and the indeterminate/hotspot separations.

29. The non-transitory machine-readable medium of claim 28, wherein designating some or all of the indeterminate spots as potential hotspots comprises:
selecting, based on the one or more thresholds and the indeterminate/hotspot separations, a subset of the indeterminate spots as potential determined hotspots; and
designating the potential hotspots from the subset of the indeterminate spots as potential determined hotspots by analyzing the indeterminate/non-hotspot separations for the potential determined hotspots.

30. The non-transitory machine-readable medium of claim 29, wherein designating the potential hotspots from the subset of the indeterminate spots as potential determined hotspots by analyzing the indeterminate/non-hotspot separations for the potential determined hotspots comprises:
determining whether a particular potential determined hotspot is closer to a known non-hotspot than a closest known hotspot; and
responsive to determining that the particular potential determined hotspot is closer to the known non-hotspot than the closest known hotspot, removing the particular potential determined hotspot from the subset of the indeterminate spots so that the particular potential determined hotspot is not included in the potential hotspots for further processing.

31. The non-transitory machine-readable medium of claim 17, wherein for the some or all of the indeterminate spots, both of the following are determined:
the indeterminate/hotspot separation between the respective indeterminate spot and the one or more closest known hotspots; and
the indeterminate/non-hotspot separation between the respective indeterminate spot and the one or more closest known non-hotspots; and
wherein the some or all of the indeterminate spots are designated as the potential hotspots based on the one or more thresholds, the indeterminate/hotspot separation, and the indeterminate/non-hotspot separation.

32. The non-transitory machine-readable medium of claim 17, wherein the one or more thresholds are customized for at least some of the known hotspots in the training dataset.
